(19) United States
(12) Patent Application Publication
(10) Pub. No.: US 2025/0029889 A1
(43) Pub. Date: Jan. 23, 2025

(54) ELECTRONIC CIRCUIT APPARATUS AND CIRCUIT-INTEGRATED MOTOR

(71) Applicant: MIKUNI CORPORATION, Tokyo (JP)

(72) Inventors: Yuki KONNO, Odawara-shi (JP); Yuji YOKOTA, Takizawa-shi (JP); Satoru FUJISAKI, Takizawa-shi (JP)

(21) Appl. No.: 18/664,527

(22) Filed: May 15, 2024

(30) Foreign Application Priority Data
Jul. 18, 2023 (JP) 2023-116696

(51) Int. Cl. H01L 23/367; H01L 23/373; H01L 23/498

(52) U.S. Cl. CPC H01L 23/3675; H01L 23/3736; H01L 23/49811

(57) ABSTRACT

An electronic circuit apparatus 1 includes: at least one semiconductor device 10; a substrate 20 installed with the semiconductor device 10 and having a through hole 24 at a position facing a back surface 17 of the semiconductor device 10; a heat sink 30 located on an opposite side of the substrate 20 from the semiconductor device 10 and having at least one protruding portion 32 protruding toward the back surface 17 of the semiconductor device 10 so as to penetrate into the through hole 24 of the substrate 20; and a heat-dissipating material 40 disposed at least between the back surface 17 of the semiconductor device 10 and a top surface 33 of the protruding portion 32 of the heat sink 30.

### TECHNICAL FIELD

The present disclosure relates to an electronic circuit apparatus and a circuit-integrated motor.

### BACKGROUND

Conventionally, an attempt has been made to promote heat dissipation from a semiconductor device serving as a heating element, in an electronic circuit apparatus in which a semiconductor device is mounted on a substrate.

For example, Patent Document 1 describes a heat dissipation structure for an in-car electronic control device, in which heat generated by a semiconductor is conducted from a heat spreader to a base via a heat via.

Patent Document 2 describes an electronic device in which a heat-dissipating member is inserted into a through hole disposed in an insulating substrate and a protruding portion of the heat-dissipating member, which protrudes on an opposite side of the insulating substrate from a semiconductor, is joined to a housing via a heat-conducting member.

### CITATION LIST

### Patent Literature

Patent Document 1: WO2015/072294A
Patent Document 2: JP2013-123011A

### SUMMARY

In the heat dissipation structure described in Patent Document 1, heat dissipation performance is not sufficiently obtained when a cross-sectional area of the heat via cannot be secured, and there is room for improvement. In addition, a processing cost to form the heat via on the substrate is high.

In the electronic device described in Patent Document 2, the heat-dissipating member is disposed separately from the housing, increasing the number of parts. In addition, a bonding material for parts, which is disposed between the heat-dissipating member and a heat sink on a back surface of an electronic component and the heat-conducting member disposed between the heat-dissipating member and the housing create heat transfer resistance, inhibiting the improvement of the heat dissipation performance.

In view of the above, an object of at least some embodiments of the present invention is to provide an electronic circuit apparatus and a circuit-integrated motor which are capable of improving the heat dissipation performance with a simple configuration where the number of parts is small and the processing cost can be reduced.

An electronic circuit apparatus according to at least some embodiments of the present invention, includes: at least one semiconductor device; a substrate installed with the semiconductor device and having a through hole at a position facing a back surface of the semiconductor device; a heat sink located on an opposite side of the substrate from the semiconductor device and having at least one protruding portion protruding toward the back surface of the semiconductor device so as to penetrate into the through hole of the substrate; and a heat-dissipating material disposed at least between the back surface of the semiconductor device and a top surface of the protruding portion of the heat sink.

According to at least some embodiments of the present invention, by causing the protruding portion of the heat sink to penetrate into the through hole of the substrate, the top surface of the protruding portion, which is a heat receiving surface of the heat sink, approaches the back surface of the semiconductor device. Therefore, the simple configuration where the protruding portion of the heat sink is inserted into the through hole of the substrate reduces heat transfer resistance in a heat transfer path from the semiconductor device to the heat sink, making it possible to improve heat dissipation performance.

### BRIEF DESCRIPTION OF DRAWINGS

FIG. 1A is a schematic cross-sectional view of an electronic circuit apparatus according to an embodiment.

FIG. 1B is a schematic cross-sectional view of an electronic circuit apparatus according to another embodiment.

FIG. 2A is a perspective view schematically showing an electronic circuit apparatus according to an embodiment.

FIG. 2B is a perspective view schematically showing an electronic circuit apparatus according to another embodiment.

FIG. 3A is a schematic plan view of an electronic circuit apparatus according to an embodiment.

FIG. 3B is a schematic plan view of an electronic circuit apparatus according to another embodiment.

FIG. 4A is a perspective view showing a specific example of protruding portions of a heat sink of the electronic circuit apparatus shown in FIG. 1B.

FIG. 4B is a perspective view showing another specific example of protruding portions of the heat sink of the electronic circuit apparatus shown in FIG. 1B.

FIG. 5 is a cross-sectional view schematically showing the overall configuration of a circuit-integrated motor according to an embodiment.

FIG. 6 is a perspective view showing a specific configuration example on the periphery of the electronic circuit apparatus of the circuit-integrated motor.

FIG. 7 is a perspective view showing a specific configuration example on the periphery of the electronic circuit apparatus of the circuit-integrated motor, and is a view where a substrate is omitted from FIG. 6.

FIG. 8 is a schematic plan view of an electronic circuit apparatus according to an embodiment.

FIG. 9 is a schematic plan view of an electronic circuit apparatus according to another embodiment.

FIG. 10 is a schematic plan view of an electronic circuit apparatus according to still another embodiment.

### DETAILED DESCRIPTION

Some embodiments of the present invention will be described below with reference to the accompanying drawings. It is intended, however, that unless particularly identified, dimensions, materials, shapes, relative positions and the like of components described or shown in the drawings as the embodiments shall be interpreted as illustrative only and not intended to limit the scope of the present invention.

Hereinafter, an electronic circuit apparatus according to some embodiments will be described with reference to the accompanying drawings. The electronic circuit apparatus described below may be an electronic control device for controlling an in-car motor. As a specific example of the in-car motor, a motor for driving a radiator fan, a motor for driving a vacuum pump, etc. can be given.

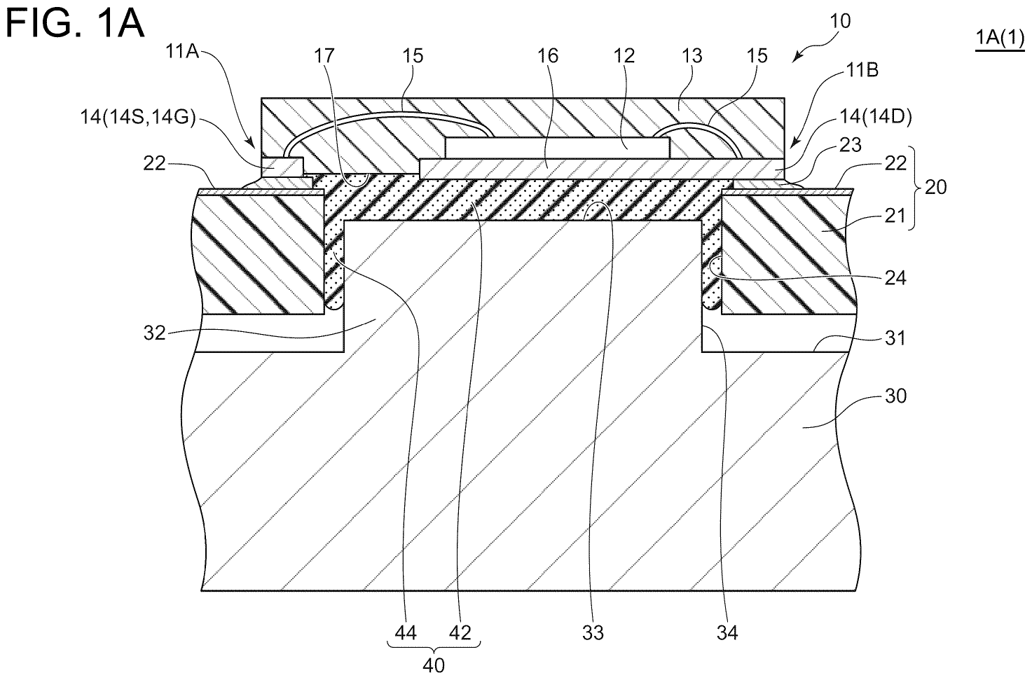

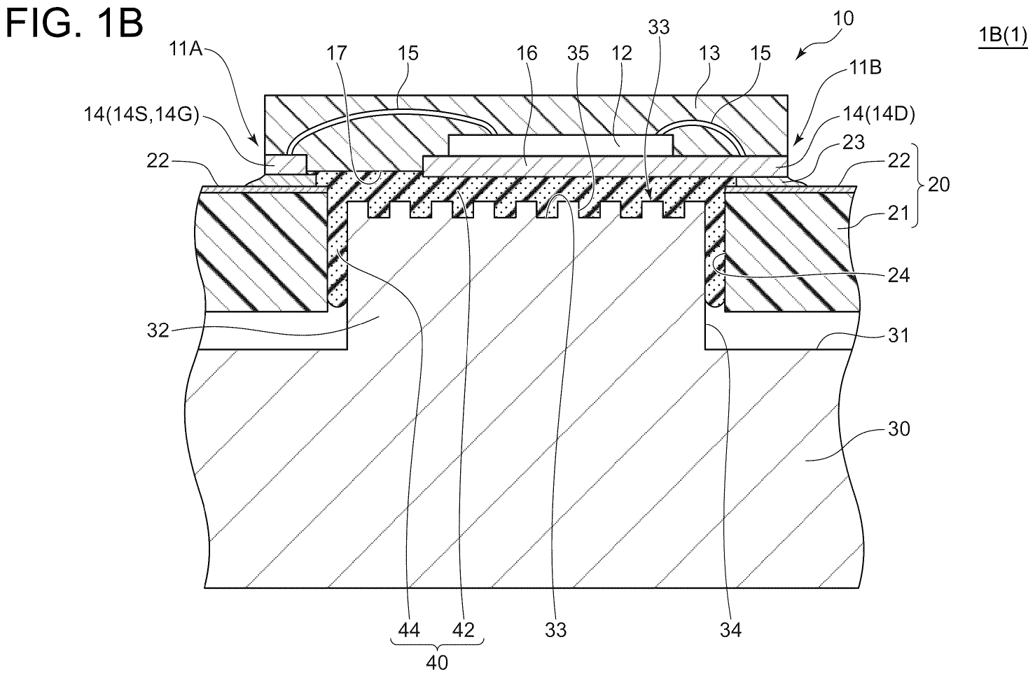

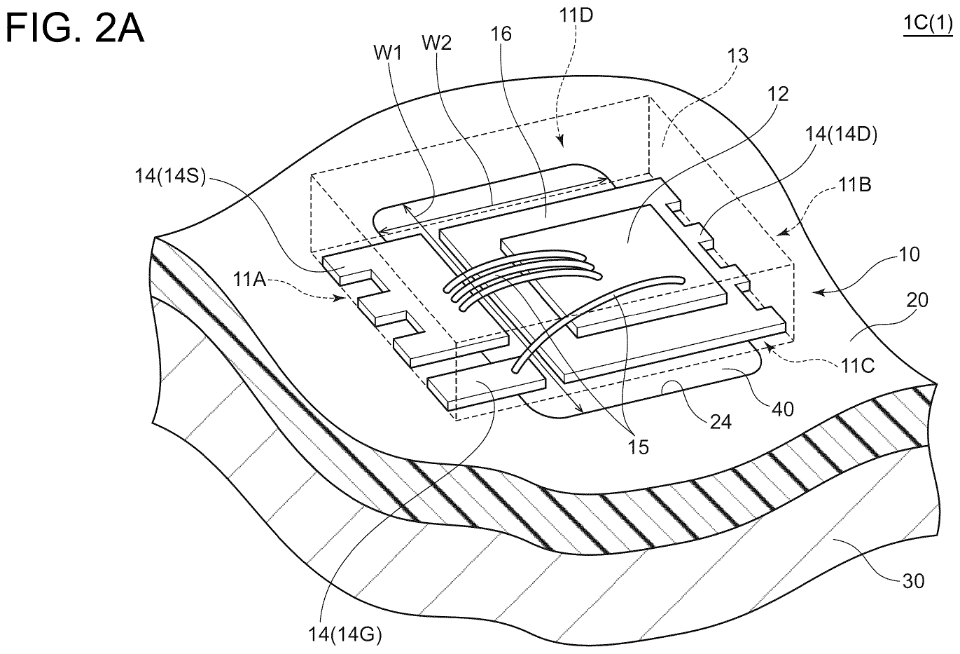

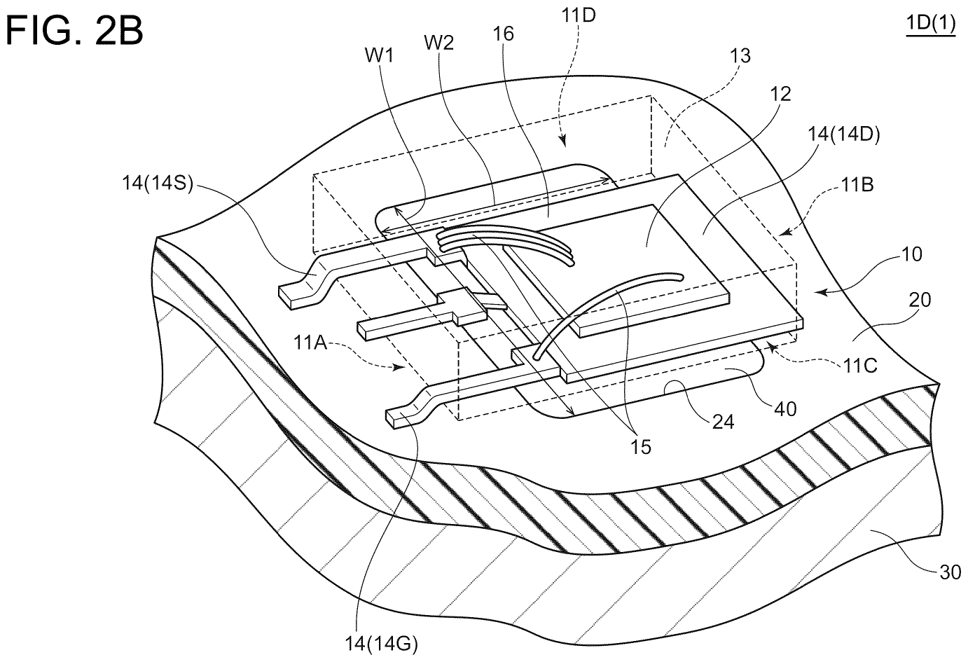

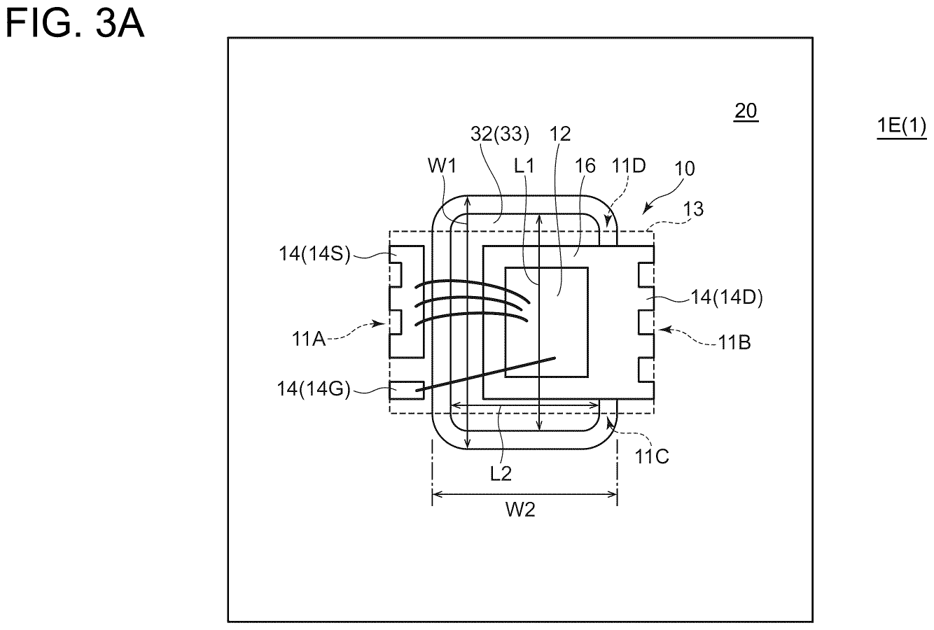

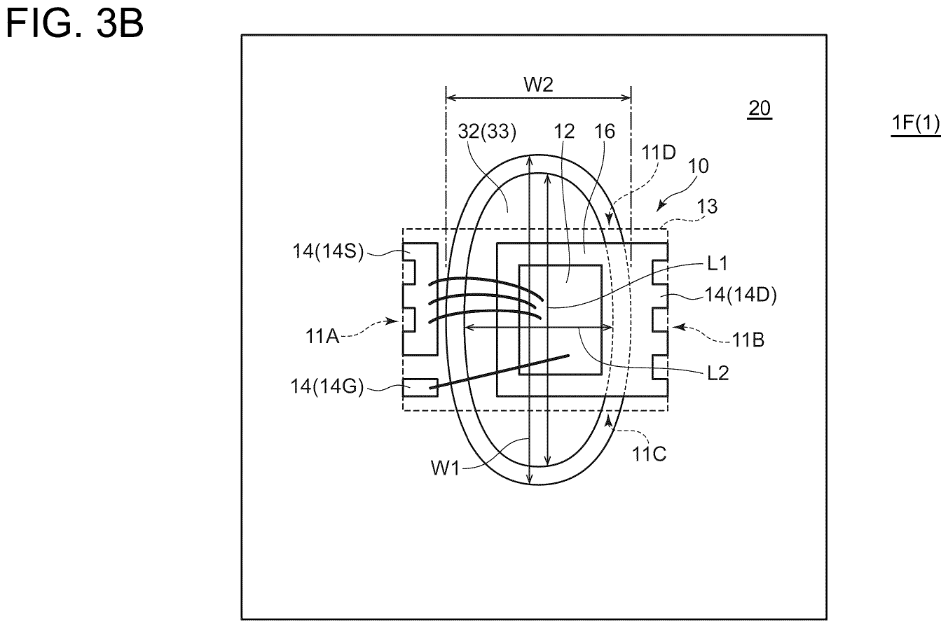

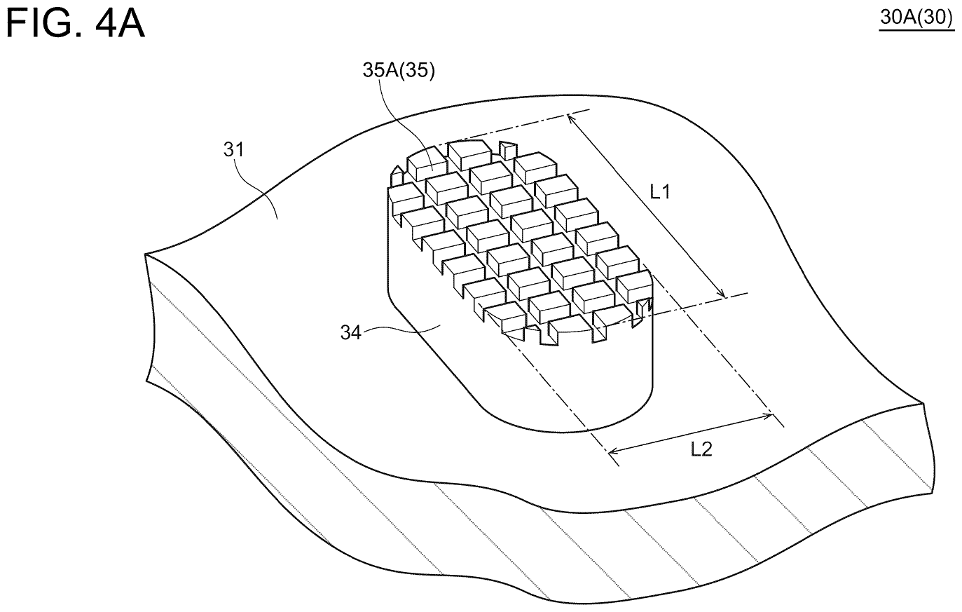

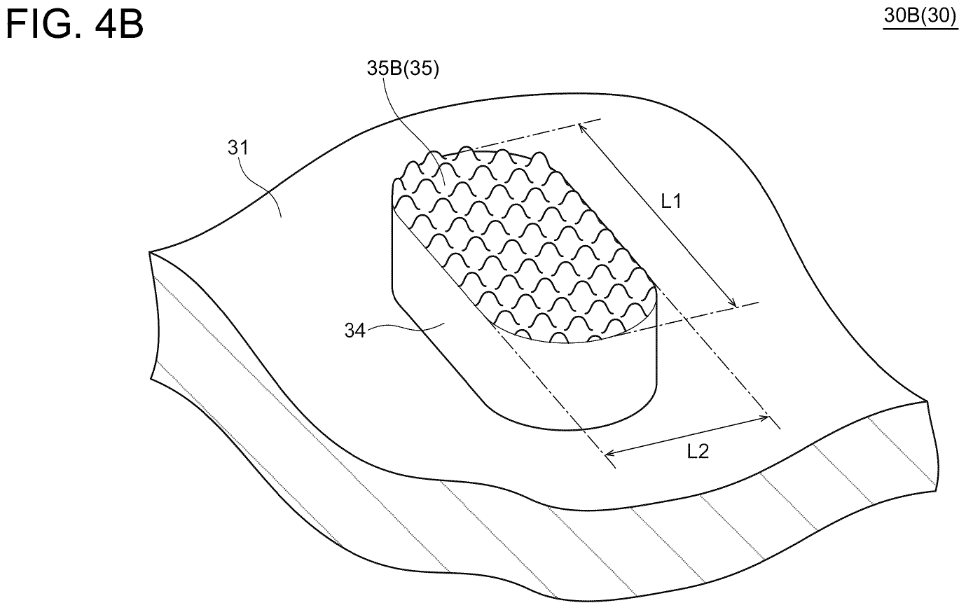

FIG. 1A is a schematic cross-sectional view of an electronic circuit apparatus according to an embodiment. FIG. 1B is a schematic cross-sectional view of an electronic circuit apparatus according to another embodiment. FIG. 2A is a perspective view schematically showing an electronic circuit apparatus according to an embodiment. FIG. 2B is a perspective view schematically showing an electronic circuit apparatus according to another embodiment. In FIGS. 2A and 2B, a package of a semiconductor device is indicated by imaginary lines. FIG. 3A is a schematic plan view of an electronic circuit apparatus according to an embodiment. FIG. 3B is a schematic plan view of an electronic circuit apparatus according to another embodiment. In FIGS. 3A and 3B, a heat-dissipating material is omitted for the purpose of showing a relationship among a through hole, a protruding portion, and the semiconductor device. FIGS. 4A and 4B are each a perspective view showing a specific example of protruding portions of a heat sink of the electronic circuit apparatus shown in FIG. 1B.

In the following description, electronic circuit apparatuses according to some embodiments, which include at least one of electronic circuit apparatuses 1A to 1F illustratively shown in FIGS. 1A, 1B, 2A, 2B, 3A, and 3B, are collectively referred to as an electronic circuit apparatus 1.

In some embodiments, as shown in FIGS. 1A to 3B, the electronic circuit apparatus 1 includes at least one semiconductor device 10, a substrate 20 installed with the semiconductor device 10, and a heat sink 30 and a heat-dissipating material 40 which form a path (heat dissipation path) for releasing heat generated in the semiconductor device 10 to the outside.

The semiconductor device 10 includes a semiconductor chip 12 and a package 13 covering the semiconductor chip 12.

The semiconductor device 10 has a form of the package 13, which is appropriate for a mount condition with respect to the substrate 20. In some embodiments, as shown in FIGS. 1A to 3B, the package 13 is a surface mount technology (SMT) type package which includes terminals 14 electrically connected to electrodes 22 disposed on a surface of the substrate 20. In another embodiment, the package 13 is an insertion mount technology (IMT) type package where a pin (lead) which is inserted into a through hole disposed in the substrate 20 and is joined protrudes from the package 13.

A specific configuration of the package of the semiconductor device 10 is not particularly limited. However, it is desirable to adopt a configuration in which terminals are disposed on at outer peripheral edge (lateral surface) of the package 13 (DIP, SOP, SOJ, SON, QFP, QFJ, QFN, etc.) rather than a configuration in which a number of terminals are arranged in lattice-like fashion on a back surface of the package 13 (PGA, LGA, BGA, etc.), in order to effectively deliver heat dissipation performance using a protruding portion 32 of the heat sink 30, which will be described later.

In the exemplary embodiments shown in FIGS. 2A, 3A, and 3B, the semiconductor device 10 of the electronic circuit apparatus 1 (1C, 1E, 1F) is of a SON (small outline nonlead) type including the terminals (pads) 14 disposed in peripheral edge portions 11A, 11B of the package 13.

In the exemplary embodiment shown in FIG. 2B, the semiconductor device 10 of the electronic circuit apparatus 1C includes the terminals 14 protruding from the peripheral edge portions 11A, 11B of the package 13.

The semiconductor chip 12 includes a semiconductor element such as a transistor, a diode, a thyristor, or the like. As the semiconductor chip 12 with high heat generation density, a power semiconductor can be given which includes MOSFET or IGBT as a semiconductor element.

The semiconductor chip 12 may be an integrated circuit (IC) with multiple semiconductor elements integrated, or a discrete chip with a single semiconductor element formed. Further, the semiconductor device 10 may be adopted which has a module structure where a plurality of discrete chips (semiconductor chips 12) are disposed in the package 13.

The semiconductor chip 12 is at least partially covered by the package 13. The semiconductor chip 12 may be embedded within the package 13. A constituent material of the package 13 is, for example, resin or ceramic.

In some embodiments, the semiconductor device 10 includes a heat-dissipating plate (heat spreader) 16 located on a back surface 17 of the semiconductor device 10. In the embodiments shown in FIGS. 1A to 3B, the heat-dissipating plate 16 is disposed to face a back surface of the semiconductor chip 12. The heat-dissipating plate 16 may be disposed in close proximity to the semiconductor chip 12 and may be adjacent to the semiconductor chip 12.

The back surface 17 of the semiconductor device 10 on which the heat-dissipating plate 16 is disposed is a surface of the semiconductor device 10, which faces the substrate 20. The heat-dissipating plate 16 is exposed to the back surface 17 of the semiconductor device 10 and faces the substrate 20.

The semiconductor device 10 includes the plurality of terminals 14 electrically connected to the semiconductor chip 12. The terminals 14 may be electrically connected to the semiconductor chip 12 via bonding wires 15 embedded inside the package 13.

In the embodiments shown in FIGS. 1A to 3B, the plurality of terminals 14 are disposed on a pair of lateral surfaces of the surface mount technology type package 13 (the peripheral edge portions 11A, 11B of the package 13). Specifically, the plurality of terminals 14 include a source electrode 14S, a gate electrode 14G, and a drain electrode 14D, the source electrode 14S and the gate electrode 14G are disposed in the peripheral edge portion 11A of the package, and the drain electrode 14D is disposed in the peripheral edge portion 11B of the package. The drain electrode 14D also serves as the above-described heat-dissipating plate (heat spreader) 16. That is, a portion of the drain electrode 14D, which faces the semiconductor chip 12, functions as the heat-dissipating plate 16 and a portion of the drain electrode 14D, which is in the vicinity of the peripheral edge portion 11B of the package 13, functions as the terminal 14.

The semiconductor device 10 having the above configuration is mounted (installed) on the substrate 20. Specifically, the semiconductor device 10 is mounted on the substrate 20 in an attitude where the back surface 17 of the semiconductor device 10 faces the substrate 20, and the terminals 14 are electrically connected to the electrodes 22 on the substrate 20. The electrodes 22 are disposed on the surface of the substrate 20 on the semiconductor device 10 side. The electrical connection between the terminal 14 and the electrode 22 may be realized by solder 23. The solder 23 is disposed between the electrode 22 and the terminal 14 to join the electrode 22 and the terminal 14.

The substrate 20 is a printed wiring board where a circuit including the electrodes 22 is formed on an insulating substrate 21. The insulating substrate 21 is formed by, for example, a composite material of glass fiber and resin.

The substrate 20 has a through hole 24 at a position facing the back surface 17 of the semiconductor device 10. A shape (contour) of the through hole 24 is not particularly limited and may have a circular shape, an oval shape, a track shape, a polygonal shape, or a shape similar to these. In the exemplary embodiments shown in FIGS. 2A, 2B, and 3A, the through hole 24 has a rectangular outer shape with corner portions curved. In the exemplary embodiment shown in FIG. 3B, the through hole 24 has an oval contour.

In some embodiments, as shown in FIGS. 2A to 3B, the through hole 24 is non-circular, and a dimension W1 of the through hole 24 along the first peripheral edge portion 11A and the second peripheral edge portion 11B of the package 13 where the terminals 14 are disposed is greater than a dimension W2 of the through hole 24 along a direction intersecting the first peripheral edge portion 11A and the second peripheral edge portion 11B (W1>W2). Herein, W1 is the longitudinal dimension of the through hole 24 and W2 is the shortitudinal dimension of the through hole 24.

In the embodiments shown in FIGS. 2A to 3B, the through hole 24 extends to the outside of the package 13 beyond other peripheral edge portions 11C and 11D of the package 13 except for the first peripheral edge portion 11A and the second peripheral edge portion 11B of the package 13, in plan view.

In an embodiment, the through hole 24 overlaps the semiconductor device 10 with an area of at least 50% of an area occupied by the semiconductor device 10, in plan view. A size of an opening of the through hole 24 may be set so as to encompass all or most of the area occupied by the semiconductor chip 12 (for example, at least 80% of the area occupied by the semiconductor chip 12) of the semiconductor device 10, in plan view. In the exemplary embodiments shown in FIGS. 3A and 3B, all of the area occupied by the semiconductor chip 12 of the semiconductor device 10 is encompassed by an opening region of the through hole 24, in plan view.

The heat sink 30 is disposed on an opposite side of the substrate 20 from the semiconductor device 10. The heat sink 30 is made of metal and is formed by, for example, copper, aluminum, or an alloy of these.

In some embodiments, the heat sink 30 has a substrate facing surface 31 facing the substrate 20 and a protruding portion 32 protruding from the substrate facing surface 31 toward the substrate 20. The protruding portion 32 of the heat sink 30 protrudes from the substrate facing surface 31 toward the back surface 17 of the semiconductor device 10 so as to penetrate into the through hole 24 of the substrate 20. That is, the substrate 20 is fixed to the heat sink 30 with the protruding portion 32 of the heat sink 30 inserted into the through hole 24.

In the embodiments shown in FIGS. 1A and 1B, a top surface 33 of the protruding portion 32 facing the back surface 17 of the semiconductor device 10 is located within the through hole 24. That is, the protruding portion 32 penetrates halfway into the through hole 24 and stops before the surface of the substrate 20 where the electrodes 22 are formed. The dimension of the protruding portion 32 is smaller than the dimension of the through hole 24. Thus, a gap exists between an outer peripheral surface 34 of the protruding portion 32 and an inner wall surface of the through hole 24.

In some embodiments, in order to increase a contact area between the heat-dissipating material 40 and the protruding portion 32, which will be described later, an outer surface of the protruding portion 32 in contact with the heat-dissipating material 40 is provided with unevenness 35, as shown in FIG. 1B. In another embodiment, the outer surface of the protruding portion 32 in contact with the heat-dissipating material 40 does not have unevenness, as shown in FIG. 1A.

In the embodiment shown in FIG. 1B, the top surface 33 of the protruding portion 32 is provided with the unevenness 35. In another embodiment, in addition to the top surface 33 of the protruding portion 32 or in place of the top surface 33 of the protruding portion 32, the outer peripheral surface 34 of the protruding portion 32 is provided with the unevenness 35. In the exemplary embodiment shown in FIG. 4A, a heat sink 30A has the protruding portion 32 with lattice-like grooves 35A (unevenness 35) formed on the top surface 33. In the exemplary embodiment shown in FIG. 4B, a heat sink 30B has the protruding portion 32 with wave-like unevenness 35B (unevenness 35) formed on the top surface 33.

In some embodiments, the protruding portion 32 has a non-circular shape corresponding to the shape of the through hole 24. Specifically, a cross-sectional shape of the protruding portion 32 along the in-plane direction of the substrate 20 has a longitudinal dimension L1 slightly smaller than the longitudinal dimension W1 of the through hole 24 and a shortitudinal dimension L2 slightly smaller than the shortitudinal dimension W2 of the through hole 24 as shown in FIGS. 3A to 4B, and satisfies L1>L2.

In the exemplary embodiments shown in FIGS. 3A and 3B, the protruding portion 32 has a non-circular contour corresponding to through hole 24, and the protruding portion 32 extends to the outside of the package 13 beyond the other peripheral edge portions 11C and 11D of the package 13 except for the first peripheral edge portion 11A and the second peripheral edge portion 11B of the package 13, in plan view.

In an embodiment, the protruding portion 32 overlaps the semiconductor device 10 with the area of at least 50% of the area occupied by the semiconductor device 10, in plan view. A size of the protruding portion 32 may be set so as to encompass all or most of the area occupied by the semiconductor chip 12 (for example, at least 80% of the area occupied by the semiconductor chip 12) of the semiconductor device 10, in plan view. In the exemplary embodiments shown in FIGS. 3A and 3B, all of the area occupied by the semiconductor chip 12 of the semiconductor device 10 is encompassed by a region of the top surface 33 of the protruding portion 32, in plan view.

The heat-dissipating material 40 is disposed at least between the back surface 17 of the semiconductor device 10 and the top surface 33 of the protruding portion 32 of the heat sink 30. When the semiconductor device 10 has the heat-dissipating plate 16 on the back surface 17, the heat-dissipating material 40 is disposed at least between the heat-dissipating plate 16 and the top surface 33 of the protruding portion 32.

The heat-dissipating material 40 is a thermal interface material (TIM) filling a gap between the semiconductor device 10 and the heat sink 30 to reduce heat transfer resistance in the heat transfer path from the semiconductor device 10 to the heat sink 30. For example, a thermally conductive grease, a thermally conductive sheet, a thermally conductive adhesive, etc. can be used as the heat-dissipating material 40. The thermal conductivity of the heat-dissipating material 40 is desirably higher than that of the substrate 20. When the terminal 14 of the semiconductor device 10 serves as the heat-dissipating plate 16, the heat-dissipating material 40 is formed by an insulating material in order to electrically insulate the terminal 14 and the heat sink 30.

In some embodiments, as shown in FIGS. 1A and 1B, the heat-dissipating material 40 includes a first portion 42 located between the top surface 33 of the protruding portion 32 and the back surface 17 of the semiconductor device 10, and a second portion 44 at least partially covering the outer peripheral surface 34 of the protruding portion 32. The second portion 44 of the heat-dissipating material 40 is connected to an outer peripheral edge of the first portion 42, and extends in a height direction of the protruding portion 32 within the gap between the through hole 24 and the outer peripheral surface 34 of the protruding portion 32 with the outer peripheral edge of the first portion 42 being a starting point.

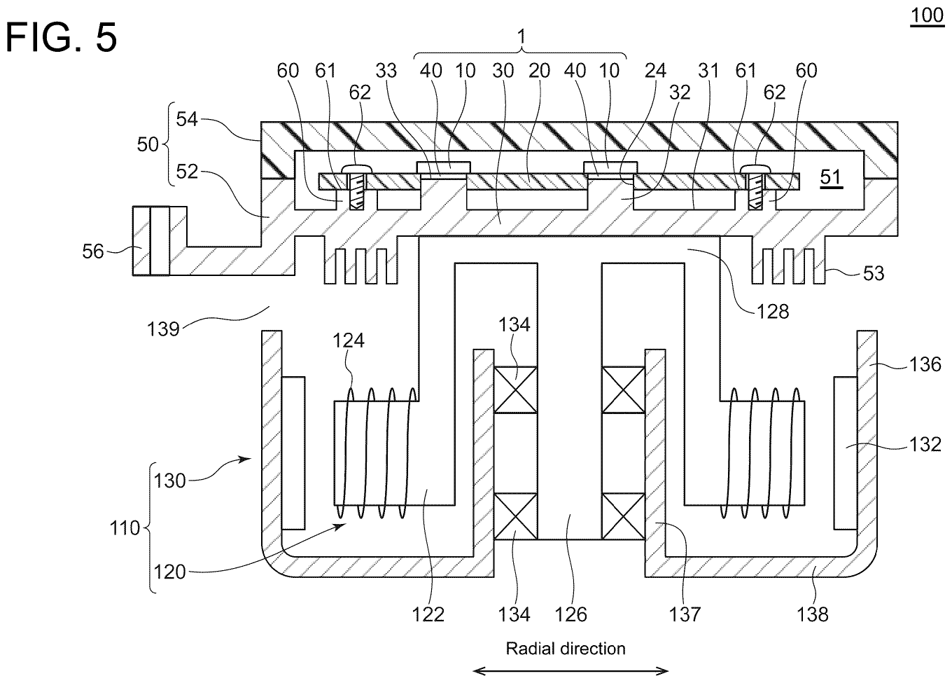

Subsequently, a circuit-integrated motor including the electronic circuit apparatus 1 will be described with reference to FIGS. 5 to 7. In the present specification, the circuit-integrated motor is an apparatus in which a motor and a control unit (control board) are integrated into a single module.

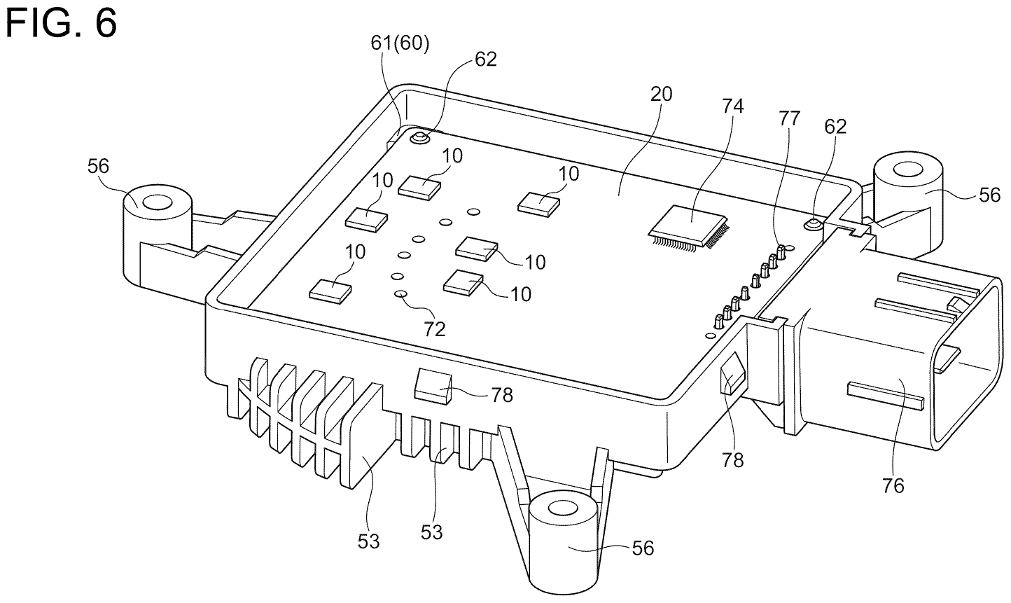

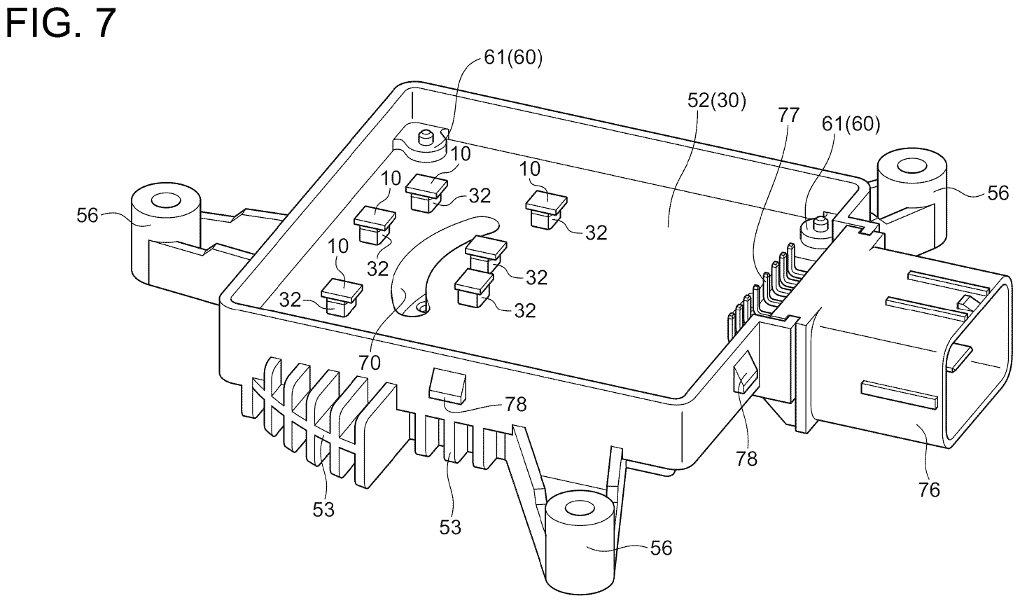

FIG. 5 is a cross-sectional view schematically showing the overall configuration of a circuit-integrated motor according to an embodiment. FIG. 6 is a perspective view showing a specific configuration example on the periphery of the electronic circuit apparatus of the circuit-integrated motor. FIG. 7 is a perspective view showing a specific configuration example on the periphery of the electronic circuit apparatus of the circuit-integrated motor, and is a view where the substrate is omitted from FIG. 6.

As shown in FIG. 5, in some embodiments, a circuit-integrated motor 100 includes the above-described electronic circuit apparatus 1 and a motor 110. The electronic circuit apparatus 1 controls the motor 110 by an inverter circuit including the semiconductor device 10 mounted on the substrate 20. In this case, the electronic circuit apparatus 1 is a control device for the motor 110, and the semiconductor device 10 is a FET configuring the inverter circuit.

In addition to the semiconductor device 10, the substrate 20, the heat sink 30, and the heat-dissipating material 40 which are described above, the electronic circuit apparatus 1 includes a casing 50 forming a substrate housing chamber 51 for housing the substrate 20.

The casing 50 includes the partition wall 52 made of metal and configured to divide the substrate housing chamber 51 from a placement region for the motor 110, and a cover 54 for forming the substrate housing chamber 51 together with the partition wall 52. In an embodiment, the cover 54 is formed of resin and is attached to the partition wall 52 by fitting in a fitting portion (not shown).

As shown in FIG. 5, the partition wall 52 serves as the heat sink 30 of the electronic circuit apparatus 1. That is, the partition wall 52 as the heat sink 30 has the protruding portion 32 protruding from the substrate facing surface 31, and is formed with a heat conduction path from the semiconductor device 10 to the protruding portion 32 via the heat-dissipating material 40.

The partition wall 52 may have a heat-dissipating fin 53 from the perspective of improving the heat dissipation performance of the heat sink 30. In the embodiment shown in FIG. 5, the heat-dissipating fin 53 is disposed on a surface of the partition wall 52 opposite to the substrate housing chamber 51, so as to face a placement space for the motor 110. In another embodiment, as shown in FIGS. 6 and 7, the heat-dissipating fins 53 are disposed on a lateral surface of the partition wall 52.

As shown in FIGS. 5 to 7, the partition wall 52 includes substrate fixing portions 60 to which the substrate 20 is attached. The substrate fixing portions 60 are located within the substrate housing chamber 51 and function to fix the substrate 20 at a predetermined position. The substrate fixing portions 60 have contact surfaces 61 which are in contact with the back surface of the substrate 20 and position the substrate 20 within the substrate housing chamber 51 in a height direction. A height position of the contact surfaces 61 from the substrate facing surface 31 is set such that the top surface 33 of the protruding portion 32 is located within the through hole 24, as shown in FIGS. 1A, 1B, and 5. Specifically, a height h of the contact surfaces 61 from the substrate facing surface 31 is set so as to satisfy 0<H−h<t, where tis a thickness of the substrate 20 and H is a height of the top surface 33 of the protruding portion 32 from the substrate facing surface 31.

In the embodiments shown in FIGS. 5 to 7, the substrate 20 is fixed to the substrate fixing portions 60 by screwing screws 62 into female screws disposed in the substrate fixing portions 60, in a state where the substrate 20 is placed on the contact surfaces 61 of the substrate fixing portions 60. In another embodiment, instead of the screwing using the screws 62, the substrate 20 is fixed to the substrate fixing portions 60 by caulking or press-fitting with protrusions disposed on the contact surfaces 61 of the substrate fixing portions 60.

In the exemplary embodiments shown in FIGS. 6 and 7, the substrate fixing portions 60 are disposed at four corners of the substrate housing chamber 51.

In addition, the partition wall 52 has an attachment portion 56 overhung radially outward. The attachment portion 56 is used to install the circuit-integrated motor 100. For example, if the circuit-integrated motor 100 is an in-car motor, the circuit-integrated motor 100 may be attached to a vehicle body via the attachment portion 56.

In the exemplary embodiments shown in FIGS. 6 and 7, six protruding portions 32 are disposed on the heat sink 30 (partition wall 52), which respectively correspond to six semiconductor devices 10 configuring the inverter circuit for controlling power supplied to the motor 110. The partition wall 52 is provided with an opening 70 (see FIG. 7) through which a motor wire (an end portion of a stator coil 124 described later) of the motor 110 passes. A gap around the motor wire in the opening 70 is sealed with a rubber material (not shown) in order to ensure sealability of the substrate housing chamber 51. The substrate 20 is provided with six through holes 72 (see FIG. 6) into which the motor wire of the motor 110 is inserted.

The inverter circuit including the semiconductor device 10 operates based on a PWM control command from a microcomputer 74 (see FIG. 6) installed on the substrate 20 and controls the power supplied to the motor 110.

The partition wall 52 is provided with a connector 76 for connecting the substrate 20 to an external device. Terminals 77 of the connector 76 are inserted into through holes disposed in the substrate 20 and are electrically connected to the circuit of the substrate 20.

A fitting projection 78 is disposed on an outer surface of a sidewall of the partition wall 52. The fitting projection 78 is used to fit the cover 54 formed of the resin and shown in FIG. 5 to the partition wall 52.

As shown in FIG. 5, the motor 110 includes a stator 120 including a stator core 122, and a rotor 130 having a magnet 132 disposed so as to face the stator core 122 in the radial direction. The stator core 122 is wound with the stator coil 124. The stator coil 124 is electrically connected to the circuit formed on the substrate 20 of the electronic circuit apparatus 1.

When a current supplied from the substrate 20 flows through the stator coil 124, the rotor 130 rotates in the circumferential direction due to interaction between the magnet 132 and a magnetic field created by the stator coil 124. Power supplied to the stator coil 124 is controlled by the inverter circuit including the semiconductor device 10.

In the embodiment shown in FIG. 5, the circuit-integrated motor 100 is an outer rotor motor in which the magnet 132 of the rotor 130 is located on an outer peripheral side of the stator core 122 of the stator 120.

Specifically, as shown in FIG. 5, the stator 120 includes the stator core 122 on which the stator coil 124 is wound, a support shaft 126 rotatably supporting the rotor 130 via a bearing 134, and a base 128 attached to the back surface of the heat sink 30 of the electronic circuit apparatus 1. The base 128 is attached to the heat sink 30 (partition wall 52) with an unshown fastening member (such as a bolt). The stator core 122 is located radially outward of the support shaft 126 so as to surround the support shaft 126. The magnet 132 of the rotor 130 is disposed on the outer peripheral side of the stator core 122. The rotor 130 has a double cylindrical structure including an outer peripheral wall 136 and an inner peripheral wall 137, and the outer peripheral wall 136 and the inner peripheral wall 137 are connected to each other via a bottom wall 138. The magnet 132 is attached to an inner peripheral surface of the outer peripheral wall 136. A vent 139 is formed between the rotor 130 and the heat sink 30 (partition wall 52). The vent 139 is formed by an axial clearance between the outer peripheral wall 136 of the rotor 130 and the casing 50 (partition wall 52).

In another embodiment, the circuit-integrated motor 100 is an inner rotor motor in which the rotor 130 is located on an inner peripheral side of the stator 120. The inner rotor circuit-integrated motor 100 has the same basic configuration as the example shown in FIG. 5, except for a positional relationship between the rotor 130 and the stator 120.

In the embodiment described above, the heat sink 30 of the electronic circuit apparatus 1 has the protruding portions 32 disposed respectively corresponding to the semiconductor devices 10 serving as heat generating elements. However, the present invention is not limited to these examples, and multiple semiconductor devices 10 may share single protruding portion 32.

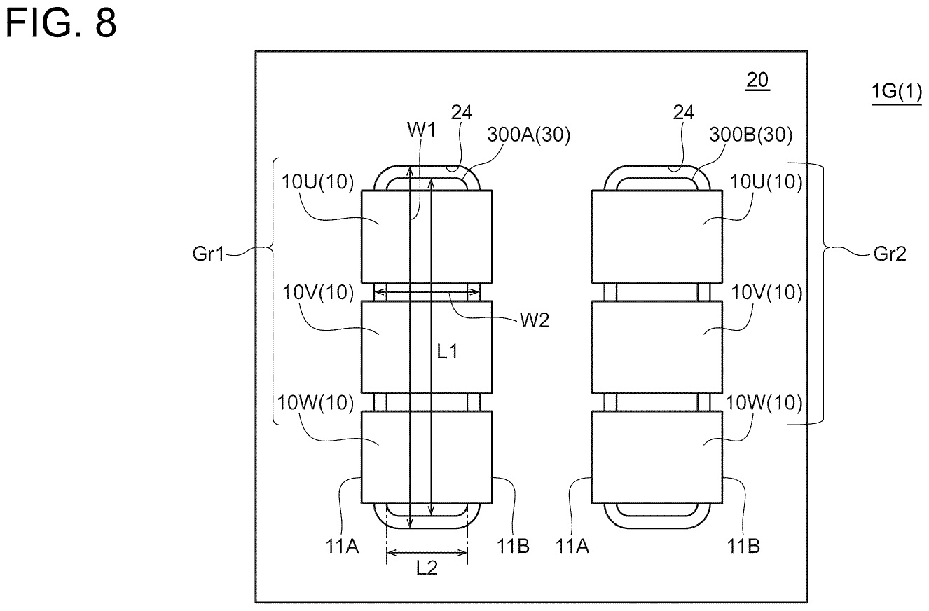

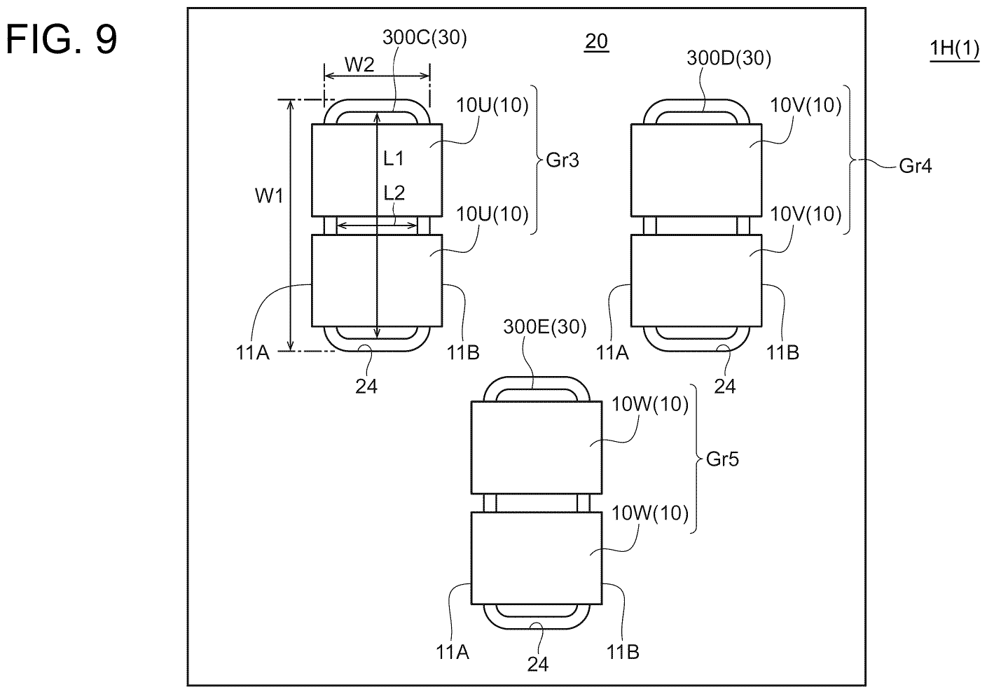

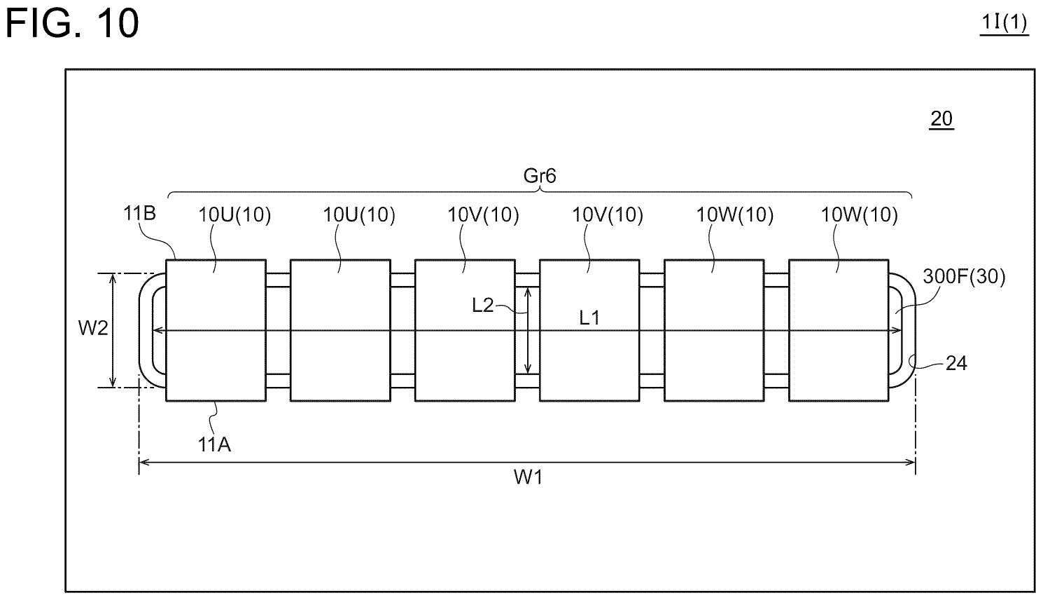

FIG. 8 is a schematic plan view of an electronic circuit apparatus according to an embodiment. FIG. 9 is a schematic plan view of an electronic circuit apparatus according to another embodiment. FIG. 10 is a schematic plan view of an electronic circuit apparatus according to still another embodiment. In FIGS. 8 to 10, the heat-dissipating material 40 is omitted.

In some embodiments, as shown in FIGS. 8 to 10, the electronic circuit apparatuses 1 (1G to 1I) include, as the protruding portions 32 of the heat sink 30, common protruding portions 300 (300A to 300F) corresponding to at least two semiconductor devices 10 among the plurality of semiconductor devices 10 mounted on the substrate 20.

In the embodiments shown in FIGS. 8 to 10, the electronic circuit apparatuses 1 (1G to 1I) include the six semiconductor devices 10 as six FETs configuring the inverter circuit for controlling the power supplied to the three-phase motor 110. The six semiconductor devices 10 include two semiconductor devices 10U corresponding to U phase, two semiconductor devices 10V corresponding to V phase, and two semiconductor devices 10W corresponding to W phase.

Each of the semiconductor devices 10 extends from the first peripheral edge portion 11A to the second peripheral edge portion 11B of the package 13 where the terminals 14 are disposed, which are described above, beyond the common protruding portions 300 (300A to 300F). Also in the electronic circuit apparatuses 1G to 1I, the relationship (W1>W2, L1>L2) among the through hole 24, the protruding portion 32 (common protruding portion 300), and the semiconductor device 10, which is described with reference to FIG. 3A, is established. That is, in the electronic circuit apparatuses 1G to 1I, the dimension W1 of the through hole 24 and the dimension L1 of the protruding portion 32 along the first peripheral edge portion 11A of the package 13 where the terminals 14 are disposed are respectively greater than the dimension W2 of the through hole 24 and the dimension L2 of the protruding portion 32 along the direction intersecting the first peripheral edge portion 11A and the second peripheral edge portion 11B.

In the exemplary embodiment shown in FIG. 8, the electronic circuit apparatus 1G includes two common protruding portions 300A, 300B respectively corresponding to two groups Gr1, Gr2 each combining the semiconductor devices 10U, 10V, and 10W corresponding to the three phases.

In the exemplary embodiment shown in FIG. 9, the electronic circuit apparatus 1H includes three common protruding portions 300C to 300E respectively corresponding to three groups Gr3 to Gr5 composed of a pair (10U, 10V, 10W) of semiconductor devices 10 corresponding to each phase.

In the exemplary embodiment shown in FIG. 10, the electronic circuit apparatus 1I includes one common protruding portion 300F corresponding to all of the six semiconductor devices 10 (10U, 10V, 10W) corresponding to the three phases.

The characteristic configurations of the electronic circuit apparatus 1 and the circuit-integrated motor 100 according to some embodiments described above are summarized as follows.

[1] An electronic circuit apparatus 1 according to at least some embodiments, includes: at least one semiconductor device (10); a substrate (20) installed with the semiconductor device (10) and having a through hole (24) at a position facing a back surface (17) of the semiconductor device (10); a heat sink (30) located on an opposite side of the substrate (20) from the semiconductor device (10) and having at least one protruding portion (32) protruding toward the back surface (17) of the semiconductor device (10) so as to penetrate into the through hole (24) of the substrate (20); and a heat-dissipating material (40) disposed at least between the back surface (17) of the semiconductor device (10) and a top surface (33) of the protruding portion (32) of the heat sink (30).

According to the above configuration [1], by causing the protruding portion (32) of the heat sink (30) to penetrate into the through hole (24) of the substrate (20), the top surface (33) of the protruding portion (32), which is a heat receiving surface of the heat sink (30), approaches the back surface (17) of the semiconductor device (10). Therefore, the simple configuration where the protruding portion (32) of the heat sink (30) is inserted into the through hole (24) of the substrate (20) reduces heat transfer resistance in the heat transfer path from the semiconductor device (10) to the heat sink (30), making it possible to improve heat dissipation performance.

[2] In some embodiments, in the above configuration [1], the semiconductor device (10) includes a heat-dissipating plate (16) located on the back surface (17) of the semiconductor device (10), and the heat-dissipating material (40) is disposed between the heat-dissipating plate (16) of the semiconductor device (10) and the top surface (33) of the protruding portion (32).

According to the above configuration [2], it is possible to increase a heat flux from the heat-dissipating plate (16) disposed on the back surface (17) of the semiconductor device (10) toward the top surface (33) of the protruding portion (32) via the heat-dissipating material (40), and it is possible to further improve the heat dissipation performance.

[3] In some embodiments, in the above configuration [1] or [2], the semiconductor device (10) includes: a semiconductor chip (12); a package (13) covering the semiconductor chip (12); a first terminal (14S, 14G) disposed in a first peripheral edge portion (11A) of the package (13); and a second terminal (14D) disposed in a second peripheral edge portion (11B) of the package (13), which faces the first peripheral edge portion (11A); and a longitudinal dimension (W1) of the through hole (24) in a direction along the first peripheral edge portion (11A) and the second peripheral edge portion (11B) of the package (13) is greater than a shortitudinal dimension (W2) of the through hole (24) in a direction intersecting the first peripheral edge portion (11A) and the second peripheral edge portion (11B), in plan view.

According to the above configuration [3], since the dimension (W1) of the through hole (24) in the direction along the peripheral edge portions (11A, 11B) of the package (13) where the terminals (14) are disposed is relatively increased, the dimension (L1) of the protruding portion (32) in the same direction is sufficiently secured, making it possible to promote heat dissipation using the protruding portion (32). Further, since the dimension (W2) of the through hole (24) in the direction intersecting the peripheral edge portions (11A, 11B) of the package (13) where the terminals (14) are disposed is relatively decreased, making it possible to secure the junction area between the terminals (14) disposed in the peripheral edge portions (11A, 11B) of the package (13) and the electrodes (22) of the substrate (20).

[4] In some embodiments, in the above configuration [3], the through hole (24) extends to outside of the package (13) beyond other peripheral edge portions (11C, 11D) of the package (13) except for the first peripheral edge portion (11A) and the second peripheral edge portion (11B), in plan view.

According to the above configuration [4], the larger dimension (L1) of the protruding portion (32) in the direction along the peripheral edge portions (11A, 11B) of the package (13) where the terminals (14) are disposed can be secured, making it possible to promote heat dissipation using the protruding portion (32).

[5] In some embodiments, in any of the above configurations [1] to [4], the top surface (33) of the protruding portion (32) is located within the through hole (24).

According to the above configuration [5], the protruding portion (32) is prevented from interfering with the semiconductor device (10) when the substrate (20) is assembled to the heat sink (30), and the credibility of the electronic circuit apparatus (1) is not impaired.

[6] In some embodiments, in any of the above configurations [1] to [5], a cross-section of the protruding portion (32) along an in-plane direction of the substrate (20) has a non-circular shape, and the through hole (24) of the substrate (20) has the non-circular shape corresponding to the protruding portion (32).

According to the above configuration [6], positioning of the substrate (20) can be done by the protruding portion (32) and the through hole (24), when the substrate (20) is assembled to the heat sink (30).

[7] In some embodiments, in the above configuration [6], the protruding portion (32) in the non-circular shape has a rectangular outer shape with corner portions curved, in plan view.

According to the above configuration [7], since the protruding portion (32) has the curved corner portions, it is possible to mitigate a stress acting on the heat-dissipating material (40) in contact with the protruding portion (32), and it is possible to suppress a decrease in heat dissipation performance due to cracking of the heat-dissipating material (40).

[8] In some embodiments, in the above configuration [6], the protruding portion (32) in the non-circular shape has an oval outer shape, in plan view.

According to the above configuration [8], since the protruding portion (32) has the curved contour, for the same reason as the above [7], it is possible to suppress the decrease in heat dissipation performance due to cracking of the heat-dissipating material (40).

[9] In some embodiments, in any of the above configurations [1] to [8], a plurality of the protruding portions (32) are disposed respectively corresponding to a plurality of the semiconductor devices (10) mounted on the substrate (20).

According to the above configuration [9], it is possible to achieve a heat dissipation effect using the protruding portion (32) as described in the above [1], while maintaining the degree of freedom in placement of the semiconductor devices (10).

[10] In some embodiments, in any of the above configurations [1] to [8], the at least one protruding portion (32) includes a common protruding portion (300) corresponding to at least two semiconductor devices (10) among a plurality of the semiconductor devices (10) mounted on the substrate (20).

According to the above configuration [10], the thermal capacity of the common protruding portion (300) is increased, making it possible to improve the heat dissipation performance.

[11] In some embodiments, in any of the above configurations [1] to [10], the heat-dissipating material (40) includes: a first portion (42) located between the top surface (33) of the protruding portion (32) and the back surface (17) of the semiconductor device (10); and a second portion (44) connected to an outer peripheral edge of the first portion (42) and at least partially covering an outer peripheral surface (34) of the protruding portion (32).

According to the above configuration [11], not only the top surface (33) of the protruding portion (32), but also the outer peripheral surface (34) of the protruding portion (32) can be used as a heat input surface, further improving the heat dissipation performance.

[12] In some embodiments, in any of the above configurations [1] to [11], the top surface (33) of the protruding portion (32) has unevenness (35).

According to the above configuration [12], the contact area between the top surface (33) of the protruding portion (32) and the heat-dissipating material (40) increases, further improving the heat dissipation performance.

[13] A circuit-integrated motor (100) according to at least some embodiments of the present invention, includes: the electronic circuit apparatus (1) having any of the above configurations [1] to [12]; and a motor (110) configured to be controlled by an inverter circuit including the semiconductor device (10) of the electronic circuit apparatus (1). The heat sink (30) of the electronic circuit apparatus (1) is a partition wall (52) made of metal and configured to divide a substrate housing chamber (51) where the substrate (20) is housed from a placement region for the motor (110).

According to the above configuration [13], the excellent heat dissipation performance described in the above [1] can be achieved by using, as the heat sink (30) of the electronic circuit apparatus (1), the partition wall (52) made of the metal and configured to divide the substrate housing chamber (51) from the placement region for the motor (110).

In the present specification, the expressions “comprising”, “including” or “having” one constitutional element is not an exclusive expression that excludes the presence of other constitutional elements.

1. An electronic circuit apparatus, comprising:
at least one semiconductor device;
a substrate installed with the semiconductor device and having a through hole at a position facing a back surface of the semiconductor device;
a heat sink located on an opposite side of the substrate from the semiconductor device and having at least one protruding portion protruding toward the back surface of the semiconductor device so as to penetrate into the through hole of the substrate; and
a heat-dissipating material disposed at least between the back surface of the semiconductor device and a top surface of the protruding portion of the heat sink.

2. The electronic circuit apparatus according to claim 1, wherein
the semiconductor device includes a heat-dissipating plate located on the back surface of the semiconductor device, and
the heat-dissipating material is disposed between the heat-dissipating plate of the semiconductor device and the top surface of the protruding portion.

3. The electronic circuit apparatus according to claim 1, wherein
the semiconductor device includes:
a semiconductor chip;
a package covering the semiconductor chip;
a first terminal disposed in a first peripheral edge portion of the package; and
a second terminal disposed in a second peripheral edge portion of the package, which faces the first peripheral edge portion; and
a longitudinal dimension of the through hole in a direction along the first peripheral edge portion and the second peripheral edge portion of the package is greater than a shortitudinal dimension of the through hole in a direction intersecting the first peripheral edge portion and the second peripheral edge portion, in plan view.

4. The electronic circuit apparatus according to claim 3, wherein
the through hole extends to outside of the package beyond other peripheral edge portions of the package except for the first peripheral edge portion and the second peripheral edge portion, in plan view.

5. The electronic circuit apparatus according to claim 1, wherein
the top surface of the protruding portion is located within the through hole.

6. The electronic circuit apparatus according to claim 1, wherein
a cross-section of the protruding portion along an in-plane direction of the substrate has a non-circular shape, and
the through hole of the substrate has the non-circular shape corresponding to the protruding portion.

7. The electronic circuit apparatus according to claim 6, wherein
the protruding portion in the non-circular shape has a rectangular outer shape with corner portions curved, in plan view.

8. The electronic circuit apparatus according to claim 6, wherein
the protruding portion in the non-circular shape has an oval outer shape, in plan view.

9. The electronic circuit apparatus according to claim 1, wherein
a plurality of the protruding portions are disposed respectively corresponding to a plurality of the semiconductor devices mounted on the substrate.

10. The electronic circuit apparatus according to claim 1, wherein
the at least one protruding portion includes a common protruding portion corresponding to at least two semiconductor devices among a plurality of the semiconductor devices mounted on the substrate.

11. The electronic circuit apparatus according to claim 1, wherein
the heat-dissipating material includes:
a first portion located between the top surface of the protruding portion and the back surface of the semiconductor device; and
a second portion connected to an outer peripheral edge of the first portion and at least partially covering an outer peripheral surface of the protruding portion.

12. The electronic circuit apparatus according to claim 1, wherein
the top surface of the protruding portion has unevenness.

13. A circuit-integrated motor, comprising:
the electronic circuit apparatus according to claim 1; and
a motor configured to be controlled by an inverter circuit including the semiconductor device of the electronic circuit apparatus,
the heat sink of the electronic circuit apparatus being a partition wall made of metal and configured to divide a substrate housing chamber where the substrate is housed from a placement region for the motor.
